(19) United States
(12) Patent Application Publication
(10) Pub. No.: US 2007/0241377 A1
(43) Pub. Date: Oct. 18, 2007

(54) Back-illuminated photo-transistor arrays for computed tomography and other imaging applications

(75) Inventors: Alexander O. Goushcha, Aliso Viejo, CA (US); Richard A. Metzler, Medina, OH (US)

Correspondence Address: BLAKELY SOKOLOFF TAYLOR & ZAFMAN, 1279 OAKMEAD PARKWAY, SUNNYVALE, CA, 94085-4040, US

(73) Assignee: SEMICOA

(21) Appl. No.: 11/786,385

(22) Filed: Apr. 10, 2007

Related U.S. Application Data
(60) Provisional application No. 60/791,333, filed on Apr. 12, 2006.
(60) Provisional application No. 60/902,986, filed on Feb. 23, 2007.

(51) Int. Cl. H01L 31/113

(52) U.S. Cl. 257/292

(57) ABSTRACT

Back-illuminated photo-transistor arrays for computed tomography and other imaging applications. Embodiments are disclosed that use bipolar transistors and JFETs, either with a single photo-sensor and transistor per pixel, or multiple photo-sensors and transistors per pixel.

### CROSS-REFERENCE TO RELATED APPLICATION

This application claims the benefit of U.S. Provisional Patent Application No. 60/791,333 filed Apr. 12, 2006 and U.S. Provisional Patent Application No. 60/902,986 filed Feb. 23, 2007.

### BACKGROUND OF THE INVENTION

1. Field of the Invention

The present invention relates to the field of photo-transistor arrays.

2. Prior Art

Part of imaging detectors (for example, a computed tomography (CT) scanner detector) is a detector array, which includes a 1-D or 2-D scintillator array that converts x-ray radiation into visible light and an attached 1-D or 2-D photodetector array that matches the above scintillator array. The photodetector array may be in the form of back-illuminated photodiode arrays, employing hundreds to thousands of PIN photodiodes arranged in a regular 1-D or 2-D matrix on a single silicon die. The back-illuminated, PIN photodiode array is a flip-chip die attached to the circuit board via either gold stud bumps with conductive epoxy, or solder bumps. Other flip-chip die attach methods can also be used. The downstream, electronics connects the outputs of PIN photodiodes to the inputs of the pre-amplifiers; each PIN photodiode is normally connected to its own pre-amplifier. Currently photo-detectors for CT scanners do not employ in-pixel amplification architecture; integration of pre-amplifier into each photo-detector pixel may provide certain advantages to the system performance (for example, improved noise performance, power consumption, etc.).

There are many publications describing photodetector arrays that allow the integration of different kinds of photo-receivers with transistors, which perform the function of the initial amplification of the detected signal. Various of these publications describe front-illuminated arrays. Some works present structures with the back-illuminated options. However, these are mainly GaAs-based structures and due to their properties and features of their design cannot be used in the medical imaging applications. Currently available Si-based back-illuminated photodetector arrays, integrated with the front-end electronics to amplify their output, employ mainly CCD and CMOS structures, which do not provide a direct addressing of each pixel of the array.

A significant amount of published work explores the features of the structure and principles of operation of the bipolar and JFET transistors integrated with PIN photodiodes. In the case of bipolar transistor, the integration is performed usually by connecting the NPN transistor base with the anode of PIN photodiode built on an N-type substrate. In the case of the photodiode built on a P-type substrate, the PNP transistor base is connected with the photodiode cathode.

For JFET integrated with PIN photodiode, several different structures were proposed. Those structures employed either the P-channel FET or N-channel FET and may work in either depletion or enhancement mode. The (photo)current integrated amplifiers as well as the (photo)charge integrated amplifiers were realized over the last decades.

### BRIEF DESCRIPTION OF THE DRAWINGS

FIG. 1 is a cross sectional view of a sample detector array structure. Each pixel of the array consists of the PIN photodiode integrated with the NPN bipolar transistor. 1 is N-type Si substrate; 2 is the anode p+ implant/diffusion; 3 is the cathode n+ uniform implant/diffusion; 4 is n+ isolating walls, not necessarily stretching across the whole die thickness; 10 is the collector n implant/diffusion; 11 is the base P implant/diffusion; 12 is the emitter n+ implant/diffusion; 21, 22, and 23 are the metal pads for the anode, cathode/collector, and emitter, respectively; 30 is Si oxide layer.

FIG. 2 is a circuit for a pixel of the sample PIN. photodiode—NPN bipolar transistor photodetector array shown in FIG. 1.

FIG. 3 is a cross-sectional view of a sample detector array structure. Each pixel of the array consists of the PIN photodiode integrated with JFET. 1 is N-type Si substrate; 2 is the anode p+ implant/diffusion; 3 is the cathode n+ uniform implant/diffusion; 4 is n+ isolating walls, not necessarily stretching across the whole die thickness; 13 and 14 are the source and drain n+ implant/diffusion, respectively; 15 and 16 are the top and bottom gate P-type implant/diffusion, respectively; 12 is the emitter n+ implant/diffusion; 21, 22, 24, and 25 are the metal pads for the anode, cathode/drain, source, and gate, respectively; 30 is Si oxide layer.

FIG. 4 is a circuit for a pixel of the sample PIN photodiode—JFET photodetector array shown in FIG. 3. The sensing resistor Rs and gate resistor Rg may be external to the structure shown in FIG. 3.

FIG. 5 is an example of the schematic top view of a single pixel of the phototransistor array with micro-pixel structures. Dashed lines 40 outline the transistor of each micro-pixel. Lines 41 connect cathodes/drains of each JFET micro-pixel (or, alternatively, cathodes/collectors of each bipolar phototransistor micro-pixel) in parallel. Lines 42 connect sources of JFET micro-pixels (or, alternatively, emitters of the bipolar phototransistor micro-pixels) in parallel.

FIG. 6 shows an example of the vertical structure of the JFET phototransistor pixel in accord with the present invention. Each pixel consists of multiple micro-pixels. Each micro-pixel includes a separate anode 2 electrically connected to the bottom gate 16 of JFET, drain 14, and source 13. The source pads 24 of all micro-pixels have to be connected in parallel either on chip or on the substrate, to which the chip is attached. The drain/cathode pads 22 of all micro-pixels also have to be connected in parallel.

FIG. 7 is similar to FIG. 6, though shows multiple micro-pixels with an integrated bipolar transistor in accordance with FIGS. 1 and 2.

### DETAILED DESCRIPTION OF THE PREFERRED EMBODIMENTS

The present invention suggests integration of the transistors into the structure of the back-illuminated, Si PIN photodiode array described recently in U.S. Pat. No. U.S. Pat. No. 6,762,473 and “The structure and physical properties of ultra-thin, multi-element Si pin photodiode arrays for medical imaging applications” (B. Tabbert et al., In Medical Imaging 2005: Physics of Medical Imaging, Proceedings of SPIE, 5745 (SPIE Bellingham, Wash., 2005), 1146-1154). The photo-transistor array of the current inventions can be built on a relatively high resistivity Si substrate, similar to the one used for building the back-illuminated, PIN photodiode arrays of U.S. Pat. No. 6,762,473, U.S. Patent Application Publication No. 2003/0209652 and U.S. Pat. No. 6,707,046. The invention describes two options for the photo-transistor arrays:

1) Bipolar transistor integrated with the PIN photodiode;

2) JFET integrated with the PIN photodiode.

Note that there are many possible ways of integrating the transistor onto the same Si substrate with the back-illuminated PIN photodiode to build arrays which are useful for imaging applications. Those solutions are not limited to the ones presented in the current description but will use similar principles.

### I. Bipolar Transistor—PIN Photodiode Back-Illuminated Array.

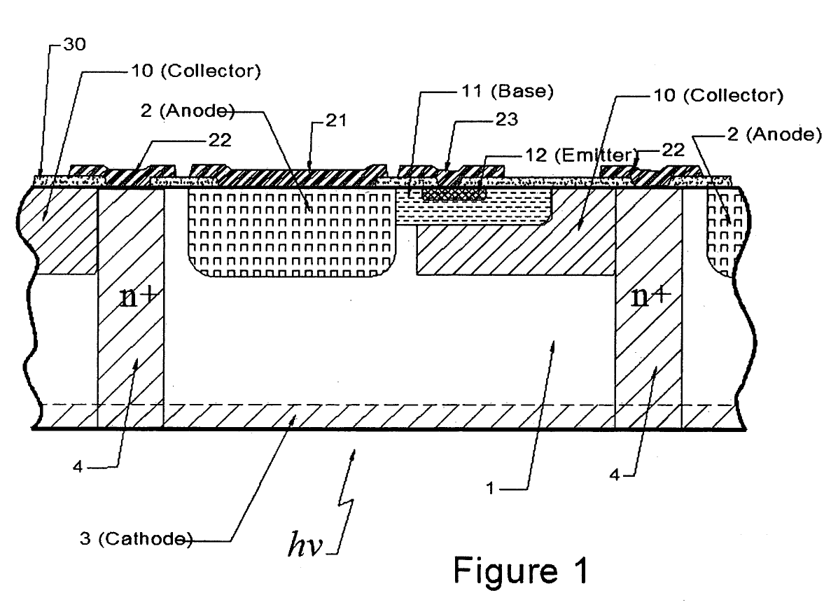

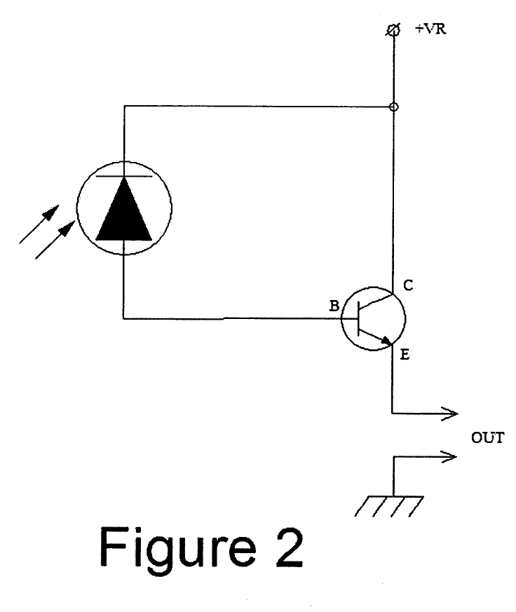

The structure of the array elements built on a high-resistivity Si wafer is shown in FIG. 1. The structure may preserve the isolation diffusion walls 4 and deep active area anode diffusion 2 described in U.S. Pat. No. 6,762,473. However, the active area diffusion may not necessarily be deep—the shallow active area diffusion is also considered as an embodiment of the invention. The same is valid for the isolation diffusion between adjacent cells—this diffusion may be shallow and may not penetrate through the whole die. The features of the PIN photodiode array structure of FIG. 1 are integrated with the bipolar transistor. The base of the bipolar transistor 11 is electrically connected to the photodiode anode 2 by being overlapping diffusions of the same material type (P-type for the NPN transistor illustrated). The collector 10, formed of the same material type as the substrate 1, is common with the photodiode cathode 3, and the N+ isolation 4, all being overlapping diffusions of the same material type (N-type in the illustration). The emitter 12 is the photo-transistor output and provides connections to the downstream electronics. A possible circuit schematic for the structure shown in FIG. 1 is presented in FIG. 2 for the N-type Si substrate and NPN bipolar transistor. An oxide passivation layer 30 is applied to the top of the silicon. Note that FIG. 1 shows a contact to region 2. This is optional, and not necessary for a proper functioning array.

The bipolar transistor—PIN photodiode array of this invention is designed on a single Si chip for application in the back-illuminated systems. The photodetector chip can be flip chip die attached to the down stream electronics using a single or multiple pads per pixel. For the bipolar NPN transistor—PIN photodiode array of FIG. 1, a single signal pad 23 is connected to the transistor emitter. The collector/cathode pads 22 can be made in the intersections of the cathode isolating walls similar to the structures described in the literature (see. U.S. Pat. No. 6,762,473 and “The structure and physical properties of ultra-thin, multi-element Si pin photodiode arrays for medical imaging applications” (B. Tabbert et al., In Medical Imaging 2005: Physics of Medical Imaging, Proceedings of SPIE, 5745 (SPIE Bellingham, Wash., 2005), 1146-1154)). The bias is applied to the collector/cathode pad, which is the transistor emitter-collector bias and at the same time a reverse photodiode bias. The anode/base pad 21 may be connected, used only for diagnostics, or eliminated.

The resistivity of the starting material can be lower than in the case of the bare PIN photodiode array to minimize the photodiode leakage current. Note that the photodiode leakage current is also the transistor base current, which determines the transistor sensitivity.

The bipolar transistor—PIN photodiode array structure shown in FIG. 1 assumes N-type Si substrate as a starting material. P-type substrates could also be used and similar structures with bipolar transistors of different polarities could be realized.

The Si substrate thickness can be 150 um or smaller; however, there is no physical limitations on the substrate thickness within the current inventions. The substrate thickness may influence some functional parameters of the array elements.

The bipolar transistor—PIN photodiode array of this invention has several advantages that might be important for CT and other imaging applications. These include low output (emitter/base junction) capacitance, high gain (>100× as compared to the bare PIN photodiode array), and fast response time (comparable to that of the PIN photodiode arrays reported recently in “Ultra-thin, two dimensional, multi-element Si pin photodiode array for multipurpose applications”, R. Metzler et al., In Semiconductor Photodetectors 2004, Proceedings of SPIE, 5353 (SPIE Bellingham, Wash., 2004), 117-125)).

### II. JFET—PIN Photodiode Back-Illuminated Array.

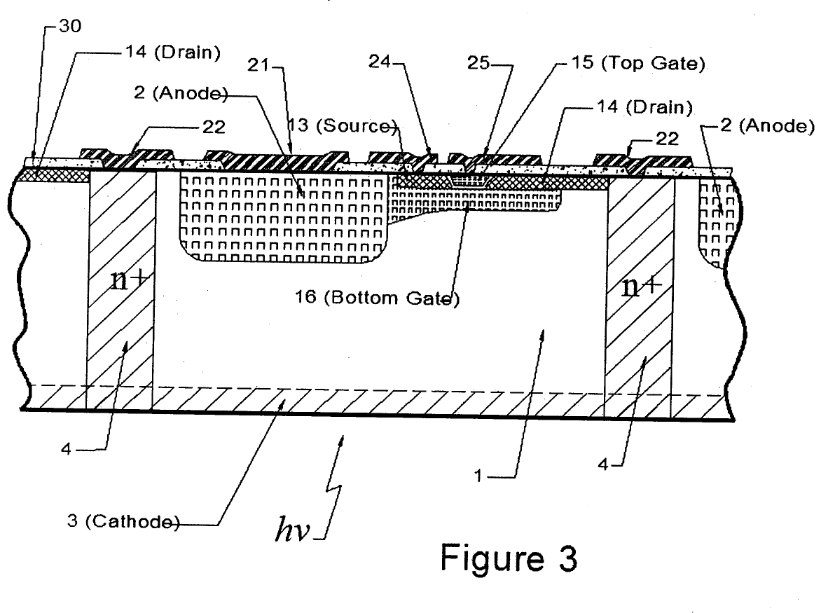

The structure of the JFET—PIN photodiode array elements built on a high resistivity Si wafer is shown in FIG. 3. The isolation diffusion 4 between the adjacent pixels (cathode deep diffusion in FIG. 3) is naturally incorporated in the design of U.S. Pat. No. 6,762,473. The active area diffusion 2 (anode diffusion in FIG. 3 described also in U.S. Pat. No. 6,762,473), is also a part of the structure. Note that both the isolation diffusion and active area implant/diffusion may not necessarily be deep. Shallow diffusions can also be integrated with the JFET and are therefore considered as an alternative embodiment of the present inventions.

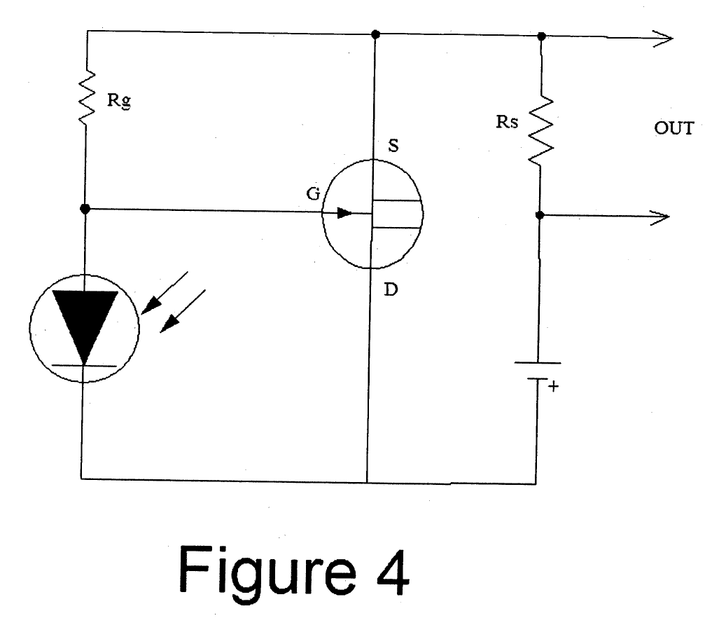

The transistor structure in FIG. 3 is an N-channel JFET working in either enhancement or depletion mode. Note that the enhancement mode provides a better sensitivity to the small optical signals. In FIG. 3, gates 16 & 15 of the JFET are common to the photodiode anode 2 (by being overlapping P-type diffusions), and the drain 14 is common to the photodiode cathode 3 (both being N-type overlapping diffusions). This JFET structure is created by applying a deep uniform p-type diffusion that serves as the bottom gate 16 for JFET. Then source and drain N-type diffusion 13-14 is made, which creates the N-type channel of JFET. At the end, a P-type implant that serves as the top gate 15 is applied. The top gate implant is driven deep enough to provide either the depletion or enhancement mode of JFET operation as desired. FIG. 3 shows contacts on region 2 and top gate region 15. These contacts are optional, and not necessary for a proper functioning array. A possible circuit schematic is shown in FIG. 4.

As in the case of the bipolar transistor—PIN photodiode array, the JFET—PIN photodiode array of this invention is designed on a single Si chip for application in the back-illuminated systems. The photodetector chip can be flip chip die attached to the down stream electronics using a single or multiple pads per pixel. For the JFET—PIN photodiode array of FIG. 3, a single signal pad for each pixel of the array is the one connected to the transistor source 13. The source may also be connected to the top gate by the gate resistor R_{G} of FIG. 4, which could be either internal or external to the silicon. The resistor value is chosen from the consideration that it should provide a proper operating potential on the transistor top gate when the photocurrent is collected by the PIN photodiode anode. In some applications this resistor value may be made infinite by eliminating it. The drain/cathode pads 22 can be made in the intersections of the cathode isolation walls similar to the structures described in the literature (U.S. Patent No. U.S. Pat. No. 6,762,473 and “The structure and physical properties of ultra-thin, multi-element Si pin photodiode arrays for medical imaging applications” (B. Tabbert et al., In Medical Imaging 2005: Physics of Medical Imaging, Proceedings of SPIE, 5745 (SPIE Bellingham, Wash., 2005), 1146-1154)). The bias is applied to the drain/cathode pad, which is the JFET N-channel bias and at the same time a reverse photodiode bias. The top gate pad 15 may be used for diagnostic testing, attached to external control circuits, or eliminated as needed for the desired application.

The JFET—PIN photodiode array structure shown in FIG. 3 assumes N-type Si substrate as a starting material. The P-type substrates could also be used and similar structures with JFETs of different polarities could be realized.

The JFET—PIN photodiode array of this invention has several advantages that might be important for CT and other imaging applications. These include low output (gate/source junction) capacitance, high gain (1000× and more as compared to the bare PIN photodiode array), and low leakage current (noticeably lower than that of the bipolar transistor—PIN photodiode array).

The back illuminated photo-transistor arrays, described in the present invention, can be used not only for CT scanners but also for other medical imaging applications such as PET, SPECT, and scanners for non-medical purposes. The advantages of the present invention designs over the conventional back-illuminated PIN photodiode arrays are applicable in numerous applications other than medical imaging applications, such as industrial CT scanners, laser ranging, vibrometers, doppler imagers, etc. Employing such arrays may also significantly improve the power load/dissipation parameters of the detector modules in comparison with the conventional design systems.

The Si substrate thickness suitable to build Bipolar—or JFET—photodetector arrays can be 150 um or smaller; however, there is no physical limitations neither from the low side nor from the high side on the substrate thickness within the current inventions. The substrate thickness may influence some functional parameters of the array elements.

One of the versions of the above described array of pin photodiodes with integrated bipolar or field-effect transistors comprises more than one transistor per each photodiode pixel. Such modified structure allows improving the pixel's dynamic range, time response, and signal-to-noise ratio due to a possibility to better match the input capacitance of the amplifying transistor with that of the photodiode sensitive element.

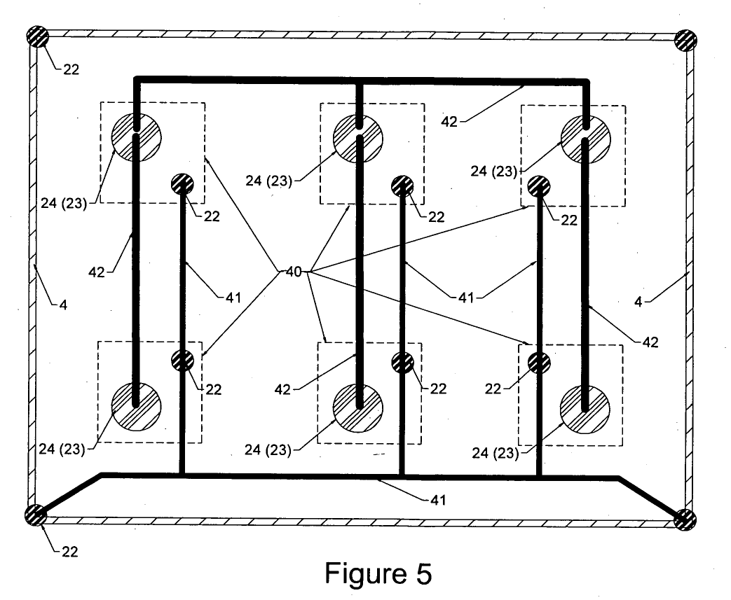

FIG. 5 shows a schematic example of the top view of a single pixel of the array with six integrated field effect transistors. Each of the transistors integrated in the pixel is shown with the squares 40. A single pixel of the photo-detector array in this case consists of several micro-pixels, connected in parallel. Similar to the structure of FIG. 3, the cathode pads 22 provide at the same time the contacts to the drain. Each micro-pixel may have its own drain pad 22; however, they all must be connected in parallel either on the chip (as it is shown in FIG. 5) or on the substrate, to which a flip-chip die attach is made. The example of the on-chip electrical connections between the drain/cathode pads 22 is shown with the lines 41. The source pads 24 of each micro-pixel are also connected in parallel with the lines 42. Such connections may be made either on chip or on the substrate.

FIG. 5 can be also thought of as a top view schematic representation of a single pixel of the bipolar phototransistor array. In this case, the pads 22 will contact the cathodes/collectors of micro-pixels, whereas the pads 23 will contact the micro-pixel emitters.

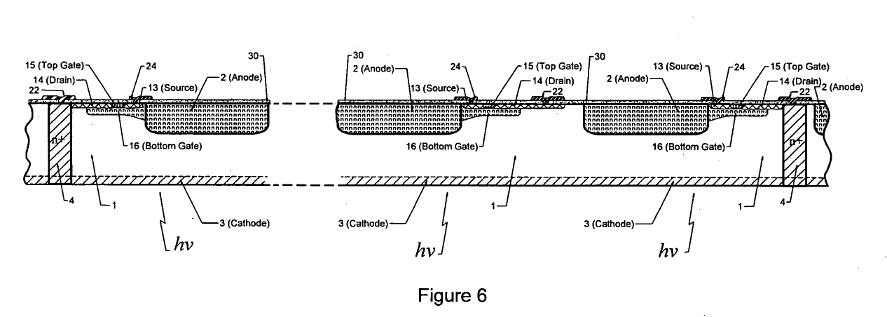

The example of the cross-sectional view of the structure containing several JFET amplifiers per pixel is presented in FIG. 6. Similarly to the structures shown in FIG. 1 and 3, each pixel of the structure in FIGS. 5 and 6 can be surrounded by the isolation diffusion 4. Note that this diffusion may not necessarily be a through diffusion. The anode diffusions 2 of micro-pixels are isolated from each other, providing thus an independent P/N junction for each micro-pixel. Under proper bias conditions, the depletion propagates from each P/N junction into the Si substrate, creating normal operating conditions for the pin diode of each micro-pixel.

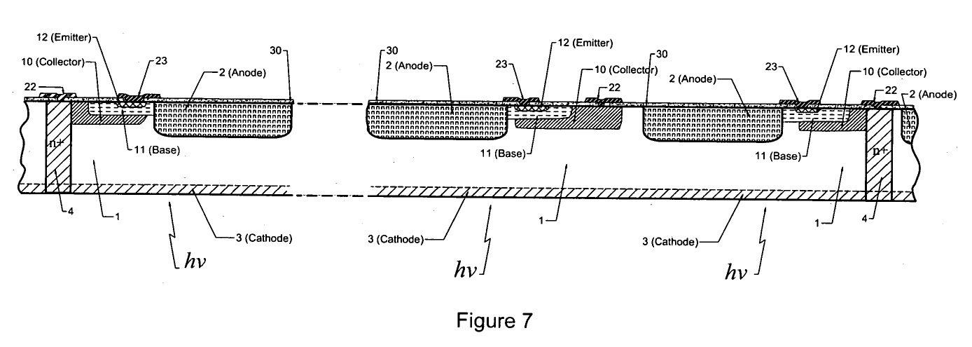

A structure, consisting of multiple bipolar transistors integrated with independent anodes (micro-pixels) can be realized for each pixel of the bipolar transistor array of FIG. 1, as shown in FIG. 7.

Note also that the described above structures with multiple bipolar or field-effect transistors per photosensitive pixel can be useful in designing not only the imaging arrays but single-pixel photodetectors as well. This allows creating high-gain, high quantum efficiency, and fast back-illuminated detectors with a large active area.

An important feature of the designs discussed in FIGS. 5, 6, and 7 is a small junction area of the photosensitive element belonging to each transistor of the whole photosensitive cell. This allows significantly decreasing capacitance and improving frequency response characteristics of the sensitive elements without compromising the other functional parameters of the detector.

Similar approach of separating the large detector pixel onto the array of connected in parallel sub-pixels can be used to build array detectors of other types, not only those photo-transistor arrays that include bipolar or junction field effect transistors. The other types of devices that provide initial amplification of photo current can be also considered. Among those are MOSFETs and many other types of field effect transistors. In addition, the arrays containing avalanche photodiodes (APDs), CCD and CMOS could be mentioned here. Note also that some realizations of the ideas presented in this invention are already available for the photodetectors consisting of the arrays of micro-pixels of Gaiger-mode avalanche photodiodes. However, the structure of the available detectors is different from what is proposed here.

What is claimed is:

1. A photo-transistor array comprising:
a substrate of a first conductivity type having first and second sides;
formed on the first side of the substrate;
a matrix of isolation regions of the first conductivity type having a higher conductivity than the substrate;
first regions of a second conductivity type interspersed within the matrix of isolation regions;
collector regions of the first conductivity type within the matrix of isolation;
base regions of the second conductivity type within the matrix of isolation regions and in contact with the first regions and the collector regions;
emitter regions of the first conductivity type within the matrix of isolation regions and in contact with the base regions; and,
contact regions electrically coupled to the emitter regions, and the isolation regions and the collector regions;
the second side of the substrate having a layer of the first conductivity type of a higher conductivity than the substrate and electrically coupled to the collector regions and the matrix of isolation regions.

2. The array of claim 1 wherein the collector regions are not in contact with the first regions.

3. The array of claim 1 wherein the collector regions are in contact with the isolation regions, and the collector regions are electrically coupled to contact regions through the isolation regions.

4. The array of claim 3 wherein the isolation regions extend from the first surface of the substrate to the layer of the first conductivity type of a higher conductivity than the substrate on the second side of the substrate.

5. The array of claim 4 wherein the layer of the first conductivity type of a higher conductivity than the substrate on the second side of the substrate is electrically coupled to the collector regions through the isolation regions.

6. The array of claim 4 wherein the isolation regions are diffused into the substrate from the first side.

7. The array of claim 4 wherein the isolation regions are diffused into the substrate from both the first side and the second side.

8. The array of claim 1 wherein the first regions of the second conductivity type do not touch the isolation regions.

9. The array of claim 1 wherein the first conductivity type is N type and the second conductivity type is P type.

10. The array of claim 1 wherein the first conductivity type is P type and the second conductivity type is N type.

11. The array of claim 1 wherein the matrix of isolation regions define an array of pixel areas, each pixel area having one first region, one collector region and one base region and one emitter region within each pixel area, the contact regions for each pixel being electrically coupled to the emitter region within the respective pixel area.

12. The array of claim 1 wherein the matrix of isolation regions define an array of pixel areas, each pixel area having a plurality of first regions, an equal plurality of collector regions, an equal plurality of base regions and an equal plurality of emitter regions within each pixel area, the contact regions for each pixel being electrically coupled to the all emitter regions within the respective pixel area.

13. A photo-transistor array comprising:
a substrate of a first conductivity type having first and second sides;
formed on the first side of the substrate;
a matrix of isolation regions of the first conductivity type having a higher conductivity than the substrate;
first regions of a second conductivity type interspersed within the matrix of isolation regions;
bottom gate regions of the first conductivity type within the matrix of isolation regions and in contact with the first regions;
source and drain regions of the second conductivity type on the bottom gate region and separated by an interconnecting channel region of the second conductivity type;
top gate regions of the first conductivity type over the channel region and in contact with the bottom gate; and,
contact regions electrically coupled to the first regions, the drain regions and the isolation regions and the source regions;
the second side of the substrate having a layer of the first conductivity type of a higher conductivity than the substrate and electrically coupled to the drain regions and the matrix of isolation regions.

14. The array of claim 13 wherein the drain regions are in contact with the isolation regions, and the drain regions are electrically connected to contact regions through the isolation regions.

15. The array of claim 14 wherein the isolation regions extend from the first surface of the substrate to the layer of the first conductivity type of a higher conductivity than the substrate on the second side of the substrate.

16. The array of claim 15 wherein the layer of the first conductivity type of a high conductivity than the substrate on the second side of the substrate is electrically coupled to the drain regions by the isolation regions.

17. The array of claim 15 wherein the isolation regions are diffused into the substrate from the first side.

18. The array of claim 15 wherein the isolation regions are diffused into the substrate from both the first side and the second side.

19. The array of claim 13 wherein the first regions of the second conductivity type do not touch the isolation regions.

20. The array of claim 13 wherein the first conductivity type is N type and the second conductivity type is P type.

21. The array of claim 13 wherein the first conductivity type is P type and the second conductivity type is N type.

22. The array of claim 13 wherein the matrix of isolation regions define an array of pixel areas, each pixel area having one first region, one bottom gate region, one source region and one drain region and one top gate region within each pixel area, the contact regions for each pixel being electrically coupled to the source region within the respective pixel area.

23. The array of claim 13 wherein the matrix of isolation regions define an array of pixel areas, each pixel area having a plurality of first regions, a plurality of bottom gate regions, a plurality of source regions, a plurality of drain regions and a plurality of top gate regions within each pixel area, the contact regions for each pixel being electrically coupled to the plurality of source regions within the respective pixel area.
